(19) United States
(12) Patent Application Publication
(10) Pub. No.: US 2011/0284374 A1
(43) Pub. Date: Nov. 24, 2011

(54) ELECTROCHEMICAL SENSOR COMPRISING A SUBSTRATE AND AN INJECTION MOULDED REACTION VESSEL AND METHOD OF ITS MANUFACTURE

(76) Inventors: Jan Krejci, Predklasteri (CZ); Zuzana Sajdlova, Brno (CZ); Lenka Chroma, Tisnov (CZ); Hana Vranova, Brno (CZ)

(21) Appl. No.: 13/145,169

(22) PCT Filed: May 12, 2009
(86) PCT No.: PCT/CZ2009/000068

§ 371 Date: Aug. 10, 2011

(30) Foreign Application Priority Data
Jan. 20, 2009 (CZ) PV 2009-22

(51) Int. Cl. G01N 27/26; H05K 13/04; B29C 45/14; G01N 27/28

(52) U.S. Cl. 204/408; 204/412; 29/592.1; 264/272.11

(57) ABSTRACT

An electrochemical sensor is described, containing a sensor substrate and at least one set of electrodes comprising a working electrode, a reference electrode and optionally an auxiliary electrode, further containing at least one reaction vessel, which is tightly connected to the sensor substrate and inside which is located at least one working electrode, whereas at least a part of the sensor substrate forms a vessel bottom. The vessel can contain a lid and also other preferred embodiments are described. The invention further describes a method of manufacture of the electrochemical sensor with the integrated reaction vessel, particularly by injection moulding.

### TECHNICAL FIELD

The invention relates to electrochemical sensor which contains a substrate, a working electrode, a reference electrode and optionally also an auxiliary electrode, further containing a reaction vessel, and to method of its production.

### BACKGROUND ART

Electrochemical detectors are important detection components in a wide range of disciplines of analytical chemistry. They are often arranged in arrays that enable simultaneous measurements of several analytes. However, it turned out that the signals are often evaluated with difficulty due to mutual interaction of individual electrode systems. P. Skládal, T. Kaláb in publications Disposable Multichannel Immunosensor for 2,4-Dichlorophenoxyacetic Acid Using Acetylcholinesterase as an Enzyme Label, Electroanalysis 9, No. 4, 1997, 293-297 and A multichannel immunochemical sensor for determination of 2,4-dichlorophenoxyacetic acid, Analytica Chimica Acta 316, 1995, 73-78 solved this problem by glueing a pad on the electrode surface, the pad containing openings that separate individual electrode systems (produced by BVT Technologies, a.s., www.bvt.cz). Similarly, the problem is solved in eight-channel sensors produced by University of Florence and distributed by Palm Instruments (www.palmsens.com), wherein individual systems of electrodes are separated by pads containing the openings.

Array of two electrodes for simultaneous monitoring of glucose and lactate levels is described in F. Palmisano, R. Rizzi, D. Centonze and P. G. Zamboni, Biosen. Biolectron. 15, 9-10(200)531. The aim of this simple array and its geometric arrangement in the channel is to eliminate the mutual influence of electrodes and the substances immobilized thereon. The simultaneous measurement and flow orientation result in the products being carried away from the electrodes and the electrodes do not affect each other. The complexity of the solutions does not allow its use in simple analyzers.

The arrays of electrodes can be used in other ways. D. J. Strike, A. Hengstemberg, M. Quinto, Ch. Kurzawa, M. Koudelka-Hep, W. Schuhmann, Mikrochim. Acta 131 (1999) 47 show an example of a four microelectrode array of the dimensions of 25 microns, which was used as a detection element for scanning electrochemical microscopy. This application relates to highly specialized applications and is not related to routine electrochemical analyses.

In the publication Jia, N. Q., Zahng, Z. R., Zhu, J. Z., Zhang, G. X., Chinese Chemical Letters 15, 3 (2004) 322 there are given the results of simultaneous measurements of glucose and galactose on an array of two electrodes. The sensor is a copy of the AC2 sensor produced by BVT Technologies a.s., www.bvt.cz. Electrochemical characteristics of the sensors were ensured by the application of ion exchange membrane (Nafion-DuPont). The membrane provides the characteristics of a silver layer as a reference electrode. The membrane was created by nafion solution application and then dried. The technical arrangement in this case shows a combination of immobilized enzymes with the ion exchange membrane, which aims to increase the electrochemical stability of the system while ensuring a reduced interaction between the electrodes.

Another exemplary arrangement of a sensor with two working electrodes is shown in the publication J. Wu, Z. Zhang, Z. Fu and H. Ju, Biosen. Biolectron. 23, 1 (2007) 114. An immuno-sensor with two working electrodes has been prepared for the determination of markers of cancer. Detection characteristics were secured by co-immobilisation of mediator and immuno-substances. The sensor was set up by printing graphite electrodes on the chip. Two competitive immuno-assays using horseradish peroxidase ensure a higher stability and a better robustness of the method. The interaction of electrodes is not fully suppressed.

Another solution has been published, where the electrochemical cell is connected to an electrode prepared by screen printing process. The electrode can be removed and replaced by another one of the same type. The cell is designed for flow analysis, and therefore contains all the inputs for the influx and outflow of liquid, input for the reference and the auxiliary electrode (Hsu, Ch.-T., Chung, Lyuu, H.-J., Tsai, D.-M., Kumar, A.S., Zen, J.-M: An electrochemical cell coupled with disposable screen-printed electrodes for use inflow injection analysis, Analytical Sciences 22 (2006) 35). The system is complicated and expensive. Other solution is shown in Chang, J.-L., Zen, J.-M.: A poly(dimethylsiloxane)-based electrochemical cell coupled with disposable screen-printed edge band ultramicroelectrodes for use in flow injection analysis, Elchem Commun 9 (2007) 2744. The cell for the screen printed microelectrode (SPME) is designed for flow measurement. The cell is made of poly(dimethylsiloxane) and SPME and it is printed onto a polypropylene substrate. The cell is designed for flow analysis in the wall jet format. The functionality was examined on detection of nitrates in the lake- (surface-) and groundwater. Similarly, the measuring cell in the publication Ke, J.-H., Tseng, H.-J., Hsu, Ch.-T., Chen, J.-Ch., Muthuraman, G., Zen, J.-M: Flow injection analysis of ascorbic acid based on its thermo electrochemistry at disposable screen-printed carbon electrodes, Sens Actuator B 130 (2008) 614 is designed for flow measurements with electrodes prepared by screen printing. The cell includes input and output of liquid, inputs for reference and auxiliary electrodes and light source input for heating the surface of the electrode, which allows for thermoelectrochemical detection. The functionality was verified for detection of ascorbic acid. Another known solution is described in U.S. Pat. No. 7,046,357. The patented solution includes the principle of biochip with a detachable microfluidic element. The microfluidic element is designed to bring the liquid with an analyte to specific reactant, which is immobilised on a certain site of the biochip. The analyte-biochip interaction can be detected by two different detectors. This solution uses different principles (surface plasma wave and mass spectroscopy) and is designed for flow analysis. The document US 2006/0160205 concerns the possibility of analysis using several biochips simultaneously. The device is designed to bear a few cartridges of biochips. These biochips may be, for example, an array of nucleic acids, allowing for a high number of samples to be analyzed. The cartridges are designed so that they can have one or more reaction cells. These cells contain the liquid influx and outflow, valves for inlet and outlet control and a pump. The solution is complex and primarily intended for complicated biochemical analyzers, e.g. of nucleic acids.

Another known embodiment is the configuration shown in US 2006/0076236. The sensor consists of a channel and an active part with an immobilised enzyme. The sensor consists of two parts that fit together. The document describes the methodology, in which the device uses two or more channels for the detection of the analyte, whereas one or more channels are covered by a membrane, and that, if necessary, can be activated by an external signal. In this way, detector lifetime may be increased. This system is also complicated. Another solution is described in the publication Lenihan, J. S., Ball, J. Ch., Gavalas, V. G., Lumpp, J. K., Hines, J., Daunert, S., Bachas, L. G.: Microfabrication of screen-printed nanoliter vials with embedded surface-modified electrodes, Anal Bioanal Chem 387 (2007) 259. Electrochemical cells are prepared by screen printing and subsequent laser ablation. These cells have volume in the order of nanoliters and the working and reference electrodes are placed on their walls. The disadvantage is the complicated sensor preparation using expensive technology. Another known solution is shown in the patent application EP 0 969 281. An electrochemical cell is proposed herein, wherein one or more striped screen-printed electrodes may be incorporated, which bear working electrode, the active material of which is modified by mercury. The electrochemical cell is used for stripping voltammetry technique. The solution shown in the publication Dong, H., Li, Ch.-M., Zhang, Y.-F., Cao, X.-D., Gan, Y.: Screen-printed microfluidic device for electrochemical immunoassay, Lab Chip 7 (2007) 1752 concerns the use of screen-printed electrodes for flow analysis. Microfluidic elements consist of a number of parts—the channel bottom wall is formed by screen-printed electrodes, channels defined by spacer form the walls and the channel top wall is formed by PDMS cover. Defined electrochemical cells for flow analysis are prepared by this method. The device is suitable for a sandwich electrochemical immunoassay using polypyrrole for binding the primary probe.

Disadvantages of the arrangement, in which the sample is applied freely onto the sensor area, are as follows:
the sample spills randomly. The geometric shape of the applied sample liquid is irreproducible, hence the mass transfer between the electrode and the bulk of sample are irreproducible, too.
only small sample amount can be applied.
the sample evaporates, which in conjunction with the preceding point may significantly change its volume.
the sample cannot be stirred.
the sample cannot be stored or it can be stored with difficulties.
measurements requiring incubation cannot be performed.
there is not a simple way to add other elements that help increase the quality of measurement and/or expand the measurement possibilities.

If a sample is applied to a well, e.g. in the eight-channel sensor produced by University of Florence and Palm Instruments, splash or run out of liquid can occur when handling the sensor. Stirring of the liquid in a small volume is very difficult, since the reaction vessel is not closed and the stirred liquid splashes and may contaminate the environment or cause a short circuit on the contacts. Another disadvantage of the existing solutions is the technology of gluing the parts forming the container or the barrier of the sensor, when contamination of the electrode active surface can occur. The adhesives are often not sufficiently chemically stable. The above listed disadvantages are, inter alia, reflected in the fact that the majority of sensors that work with small volumes are based on the flow principles. However, this brings other disadvantages, especially capillaries connection, need for pumps, chip (sensor) and analyzer connection, which increase the price of analysis and hinder the use of sensors as cheap routine analyzers.

The above-mentioned disadvantages are overcome by the present invention.

### DISCLOSURE OF INVENTION

Object of the present invention is an electrochemical sensor, which contains a sensor substrate and at least one set of electrodes, which comprises a working electrode, a reference electrode and optionally an auxiliary electrode, the sensor containing at least one reaction vessel, which is tightly connected with the sensor substrate and inside which is located at least one working electrode, whereas at least part of the sensor substrate forms the vessel bottom.

The tight connection of the reaction vessel with the sensor substrate is such a connection, in which there is no leak of liquid through the connection, therefore it is an impervious connection.

The sensor substrate can be made of any material the use of which for this purpose is known to a person skilled in the art, particularly of corundum ceramics, glass or corundum.

The sensor substrate can be provided with a heating element and optionally also with a temperature measuring element, as described in the patent application PCT/CZ2008/000048 (WO 2008/131701). This solution allows to achieve better mass transport to the working electrode and temperature stimulation of the processes inside the reaction vessel during the measurement.

It is an aspect of the invention that the reaction vessel is produced by injection moulding. The technology of injection moulding is well known to a person skilled in the art. It usually comprises the following procedure: The sensor or its part is inserted into a steel hardened mould. A plastic material is injected under the pressure of 1 to 1000 MPa at the temperature of 100 to 300° C., which surrounds the sensor in the locations defined by the mould, simultaneously creating the desired shape and the tight connection of the vessel and the sensor. The mould is cooled and the injection proceeds very fast, thus the plastic material fills the whole mould. Then the plastic material cools down and shrinks. The mould is opened and the product is taken out. A typical cycle of the production process takes 1-10 s. There are many materials the use of which is known for this technology. Most common are polyethylene, variously branched and with various molecular weight, polypropylene, variously branched and with various molecular weight, ABS (acryl nitrile butadiene styrene), PBT (polybutylene terephthalate), PET (polyethylene terephthalate), polystyrene, polymethyl methacrylate, and many others, which are known to those skilled in the art. All materials may contain up to 30% of fillers. Glass is an example of filler. Fillers are in the form of bullets or needles and they influence the final solidity of the product. Due to the use of injection moulding technology, the tight and impervious connection of the reaction vessel with the sensor substrate can be achieved. The injection moulding technology enables also the production of reaction vessels of complex shapes at low cost and high precision, as it is shown in the examples below.

The reaction vessel comprises a base and a shell. The base is formed below the sensor substrate (on the bottom side of the sensor substrate, i.e., it is on the opposite side of the substrate than are the electrodes) and it is connected with the shell only in a part of the bottom rim of the shell. The reaction vessel can be substantially of cylindric or prismatic shape. The reaction vessel is formed so that its part overreaches the sensor substrate surface and the connection of the reaction vessel base with the part of the bottom rim of the shell is created right in this location. The reaction vessel can be closed by a lid, while the closure may be hermetically tight. The reaction vessel may be inseparably connected with the lid, e.g. by means of a flexible element allowing the lid closing and, if needed, also a lid re-opening. For instance, a light source or a photodetector can be placed in the lid, if the analytical reaction employed is a photoreaction or if the reaction product emits light.

In a preferred embodiment, the reaction vessel height is 1 to 20 mm, the reaction vessel inner diameter is 1 to 20 mm the reaction vessel inner shape can be, e.g., of cylindric shape with a circular or an elliptical base or of cylindric shape with an oval base or of prismatic shape, the edges of which are perpendicular to the sensor surface and are curved with the curvature radius of 0.1 to 5 mm, or of the shape of ellipsoid.

The advantage of the reaction vessel and the sensor substrate tight connection is the formation of a space, which is separated from the surrounding environment, and in which it is possible to carry out sample measurements and procedures such as sample stirring, reactions, incubations and others without the risk of affecting the electrodes that are located in the neighbourhood of the reaction vessel or the surrounding environment contamination by the chemicals used for the analysis.

A further advantage of the invention is that the reaction vessel enables to define the contact area of the sample with the working electrode. For this purpose, a reaction vessel with conical inner side of the shell or conical part of the inner side of the shell (blunted cone shape) tapering towards the working electrode may serve, focusing the analysed solution onto the working electrode, whereas, in a preferred embodiment, a conductive membrane with a circular opening, the diameter of which is bigger than the working electrode diameter and smaller or equal to the diameter of the reaction vessel inner side of shell conical part ending, can be inserted between the reference and auxiliary electrodes at one side and the inner space of the reaction vessel at the other side. This membrane ensures a conductive connection between the analysed solution and the auxiliary and reference electrodes, without them being in direct contact with the analysed solution.

In another preferred embodiment of the invention, the inner shell side of the reaction vessel and the inner side of the lid can have the shape of ellipsoid surface or of a part of ellipsoid surface, preferably of an ellipsoid with the focus identical with the working electrode location. This embodiment is mostly preferred for carrying out the reactions, which are stimulated by light, or reactions, in which light is formed (electroluminiscence). Preferably, a light source, e.g., LED, or a photodetector is positioned in the second focus of the ellipsoid. Also preferably, the inner shell side of the reaction vessel and the inner side of the lid are covered by a material that reflects light. The inner shell side of the reaction vessel and the inner side of the lid can also be covered by a chemically indifferent material with a high optical transmittance, e.g., by polymethyl methacrylate, glass or poly styrene. Both layers can be used at once, then the inner shell side of the reaction vessel and the inner side of the lid is covered by the material that reflects light first and subsequently by the chemically indifferent material.

The reaction vessel lid can contain a substance that influences properties such as stability of electrode materials and/or substances in the reaction vessel or it can contain reagents. At least part of the reaction vessel lid can be constructed from an elastic material and the lid, optionally also the vessel is then closed by a membrane made of a brittle material, e.g., glass. The elastic part of the lid is squeezed after the vessel is closed by the lid, hence the membrane made of brittle material is broken and the lid content is mixed with the vessel content.

Electrochemical sensors equipped with the reaction vessels can be arranged in sensor arrays. In this embodiment it is useful when the electrochemical sensors contain connecting elements, e.g. locks and cut-outs or notches for inserting corresponding connecting elements.

Another possible embodiment is a combination of the reaction vessel with elements, which allow influencing the processes on the working electrode without affecting other electrodes. These elements may be, for instance, an element focusing magnetic field on the working electrode, which is, e.g., a truncated cone-shaped magnet, with a smaller base heading to the working electrode. In such a case the reaction vessel base contains a cut-out corresponding to the shape of the element, which influences the working electrode processes. The element influencing the working electrode processes can be tightened inseparably to the sensor or detachably inserted to the corresponding cut-out in the reaction vessel base.

Object of the invention is also a method of manufacture of the electrochemical sensor containing the reaction vessel, comprising an injection moulding step, in which a sensor or its part is inserted into a mould, which is shaped so that it is possible to achieve the above described reaction vessel shape containing the base and the shell, a plastic material is injected into the mould under the pressure in the range of 1 to 1000 MPa and the temperature in the range of 100 to 300° C. and the resulting product is then cooled. Hot plastic material forms the reaction vessel base on the bottom side of the sensor substrate and the reaction vessel shell on the top side of the sensor substrate, which contains working electrode(s), while in the part of the reaction vessel overreaching the surface of the sensor substrate is formed the connection of the base with the part of the shell bottom rim. At cooling, the plastic material shrinks, thus creating pressure forces of the reaction vessel base against the bottom side of the sensor substrate and pressure forces of the reaction vessel shell against the top side of the sensor substrate, thereby the tightness of the connection is ensured, i.e. the connection impermeability to liquids, and thus the isolation of the sensor part located inside the reaction vessel is ensured. This connection is also unseparable and undemountable. The advantage of said production method is that the vessel is formed on the sensor in a single step.

In another embodiment of the invention, the reaction vessel can also be produced by a process, in which the base and the shell are produced independently and separately from the sensor substrate, the base is put below the substrate onto the opposite side than that on which the electrodes are placed and the shell is put onto the substrate so that inside it is the working electrode, and a sealing element, e.g., an o-ring, is inserted between the shell and the substrate, and the base and the shell are then connected by a mechanical connecting element, e.g., a lock.

The disadvantages of the solutions known in the prior art are overcome by the invention in such a way that the reaction vessel is made of a plastic material and it is attached to the sensor surface containing the active electrodes by means of injection moulding in such a way that a single compact and tight unit is formed, which may include also a lid allowing closing the vessel. The lid can be filled with chemicals, closed, stirred, e.g., by vibration method or shaking. The sensor according to the invention may also be used so that lyophilized reagents required for its use are prepared in closed vessels. The analytical method may be pre-prepared for users to a large extent, which increases the operator's comfort and allows for performance of complex chemical analyses (in terms of the chemicals preparation) by a nonspecialist user without the need for special equipment (weights, chemical technology for the sample preparation).

Combining the injection moulding process with the sensors prepared on the ceramic surface, for example according to CZ patent 291411, it is possible to prepare not only simple systems, which overcome some of the disadvantages of the prior art, but also completely new layouts, which can be difficult to make by heretofore known procedures. A sufficiently small working volume significantly saves chemicals consumption. A sufficiently small volume and overall dimensions allow for diffusion to be sufficient to equilibrate the concentrations. As it is possible to close the unit hermetically after the sample introduction, it is possible to use a reasonably longer periods without volume being influenced by evaporation. The sensor with the sample can also be mechanically stirred for instance by shaking. As the sensor with the vessel creates a unit, which can be hermetically closed, it is possible to supply the sensor with all the reagents necessary for the analysis or to use materials the use of which is dangerous for conventional sensors, e.g., mercury. Minimum surrounding environment contamination possibility can be reached in case of using dangerous materials. A further advantage of the sensors according to the invention is the possibility of using nanostructured working electrodes. Detection characteristics of electrodes can be significantly increased by creating nanostructures. However, there is a problem of manipulation with the electrodes with nanostructured surfaces without damaging the surface. The invention enables this by providing the sensor forming with the reaction vessel an inseparable entity, which can be hermetically closed. The invention is further explained by way of examples of embodiments in connection with attached drawings without being limited by them.

### FIGURES

FIG. 1 shows the electrochemical sensor in the embodiment of Example 1 at side view and top view and also the embodiment of the sensor with the heated substrate.

FIG. 2 shows the mould and the embodiment of the sensor manufacturing process of Example 1.

FIG. 3 shows the sensor response record at acetylcholine esterase inhibitor concentration measurement according to Example 1.

FIG. 4 shows the detail of a single sensor response of FIG. 3.

FIG. 5 shows the calibration curve for Syntostigmin concentration determination according to Example 1.

FIG. 6 shows the electrochemical sensor in the embodiment of Example 2 at side view and top view.

FIG. 7 shows the electrochemical sensor in the embodiment of Example 3 at side view, detailed view of the bottom part of the vessel and the sensor substrate part with the electrodes and the membrane detail.

FIG. 8 shows an array of electrochemical sensors in the embodiment of Example 4, detailed view of the reaction vessel and detailed view of its shell with connecting elements.

FIG. 9 shows an array of electrochemical sensors in the embodiment of Example 4, detailed view of the reaction vessel shell with connecting notches and detailed view of a single sensor with the connecting element.

FIG. 10 shows the electrochemical sensor in the embodiment of Example 5 and the vessel detail.

FIG. 11 shows the electrochemical sensor in the embodiment of Example 6 and the vessel detail.

FIG. 12 shows detailed view of the relationship of working electrode radia and the top base of the conical cut-out according to Example 6.

FIG. 13 shows a part of the electrochemical sensor in the embodiment of Example 7.

FIG. 14 shows the electrochemical sensor in the embodiment of Example 8.

FIG. 15 shows the sensor response record during the K₃[Fe(CN)₆] electrode potential determination according to Example 8.

FIG. 16 shows the sensor response detail of Example 8 at optical stimulation.

FIG. 17 shows the electrochemical sensor in the embodiment of Example 9.

FIG. 18 shows the electrochemical sensor in the embodiment of Example 10.

FIG. 19 shows the electrochemical sensor in the embodiment of Example 11.

FIG. 20 shows the electrochemical sensor at setup according to Example 12 and detail of the vessel base.

FIG. 21 shows the two dimensional sensor array according to Example 12 and detailed view of the contacts for sensor connection.

FIG. 22 shows the electrochemical sensor in the embodiment of Example 13.

FIG. 23 shows the electrochemical sensor in the embodiment of Example 14.

FIG. 24 shows the electrochemical sensor in the embodiment of Example 15.

FIG. 25 shows the electrochemical sensor in the embodiment of Example 16.

### EXAMPLES

### Example 1

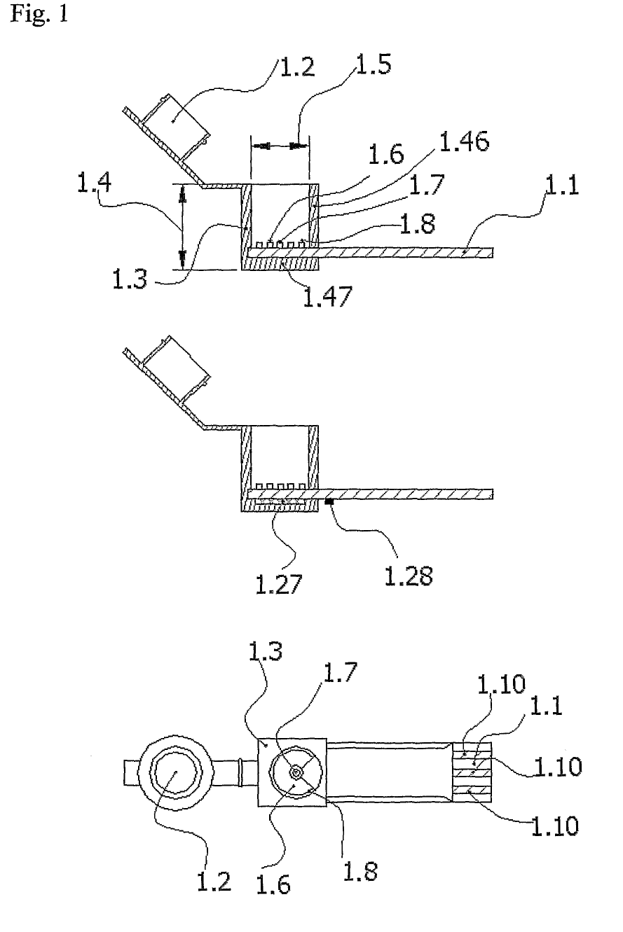

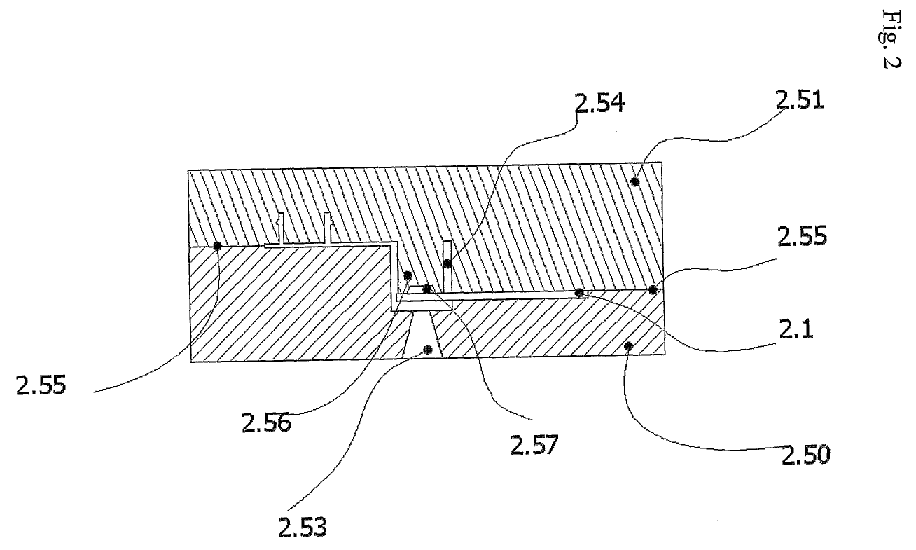

Electrochemical sensor according to Example 1 is schematically represented in FIG. 1 and it consists of a ceramic sensor substrate 1.1, onto which a working electrode 1.7 a reference electrode 1.6 and an auxiliary electrode 1.8 are applied. These electrodes are deposited by e.g. screen printing technology (sensor formation on the substrate 1.1 can be carried out according to patent CZ 291411 or according to other embodiments presented on www.bvt.cz). A reaction vessel 1.3 having the height 1.4 and the reaction space diameter 1.5, having a base 1.47 and a shell 1.46, is applied by injection moulding onto the electrochemical sensor substrate so that it creates a separated space above and around the sensor active area. The vessel 1.3 can be made of, e.g., polypropylene. The vessel can be equipped by a lid 1.2. The sensor with the integrated reaction vessel according to the invention is connected to the evaluating unit by means of contacts 1.10. Its production procedure is schematically shown in FIG. 2.

Preferably, the sensor can be equipped with a heating element 1.27 and a temperature measurement element 1.28, as described in patent application PCT/CZ2008/000048 (WO 2008/131701).

The sensor 2.1 is inserted into the bottom part of a mould 2.50. The material of the mould is, e.g., tool steel 52 HRC. The mould is closed by its top part 2.51, thereby a closed space 2.54 is created, which has the shape of the reaction vessel and the part of which is also the sensor 2.1. The top part 2.51 of the mould and the bottom part 2.50 of the mould are separated by separating planes 2.55, the position of which is important for the product quality. In the top part 2.51 of the mould there is created a supporting component 2.56, which supports the inserted sensor and thus prevents its breaking or deformation during the material injection. The support component 2.56 is at the end equipped with an appropriate cut-out 2.57 which protects the working electrode(s) surface, preferably furnished with nanostructure increasing their sensitivity, against damage or contamination by the injected material. Once the form is put together, the injector 2.53 injects molten plastic material such as polypropylene, polyethylene, xantoprene, desmopan, ABS (acryl nitrile butadiene styrene), PBT (polybutylene terephthalate), PET (polyethylene terephthalate), polystyrene, or polymethyl methacrylate. The procedures schematically described above are carried out by a semiautomatic device for injection moulding so that the production cycle, including the insertion of the sensor, takes less than 10 s. The device also provides and controls other technological requirements needed for the production (accurate mould setup, pressure of the melted plastic material in the range of from 1 to 1000 MPa, preferably in the range of from 1 to 100 MPa, plastic material temperature in the range of from 100 to 300° C., accurate mould opening and product withdrawal). These parameters' setting is known to those skilled in the art of injection moulding.

The production procedure is the same in all following examples. In each example it is necessary to make a mould containing support components that hinders the sensor breaking and protects its active surfaces. The mould defines a reaction vessel shape as well.

Example of the sensor use for measurement of acetylcholinesterase (AChE) inhibitor concentration: The sensor was prepared by the procedure described above. AChE enzyme was immobilised on the working electrode of the completed sensor. The sensor was inserted into the connector connected with analytical unit BA1 (BVT Technologies, a.s., www.bvt.cz), which reads current originating in electrochemical reaction, transforms it to digital form and transfers it for further processing and evaluation to a PC.

The following reaction is used in the measurement: Reaction substrate ATCh (acetylthiocholine) is catalytically dissociated using AChE enzyme to create electroactive product thiocholine and acetic acid. The electrochemical measurement detects the current response of the electroactive product thiocholine, which is directly proportional to its concentration.

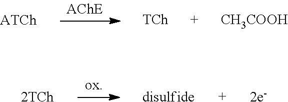

After the addition of an inhibitor, e.g., Syntostigmin, an AChE enzyme activity decrease occurs (inhibition), resulting in the current signal decrease.

The rate of the current decrease observed after the inhibitor addition, expressed as dI/dt, is proportional to the inhibition activity of the given substance. The relative inhibition variable, which expresses the current relative decrease, is used for the evaluation of the measured dependences,

$$RI = \frac{\frac{d I}{d t}}{{I}_{SS}}$$

wherein Iss is equilibrium (steady-state) current after substrate addition (P. Skládal: Detection of organophosphate and carbamate pesticides using disposable biosensors based on chemically modified electrodes and immobilized cholinesterase, Anal. Chim. Acta, 269, 281-287 (1992)).

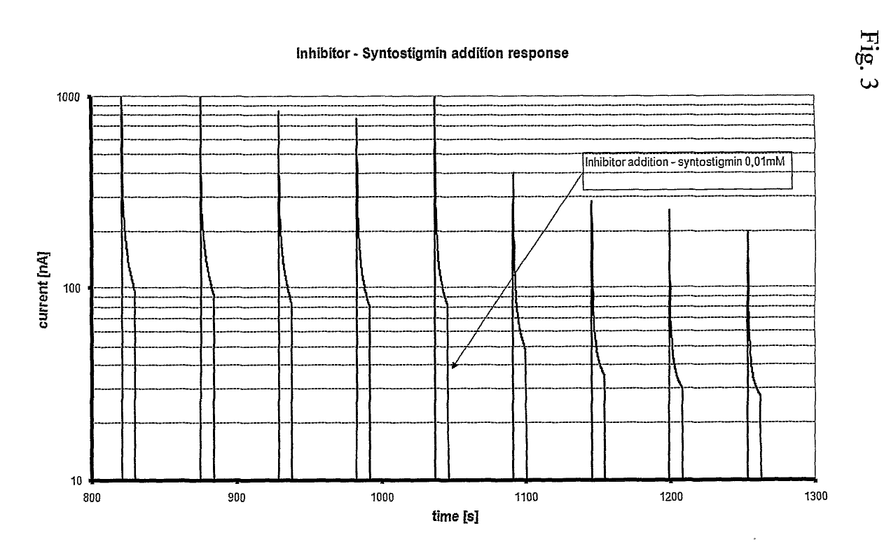

The measurement was carried out without stirring. Reaction of substrate ATCh with the enzyme occurs spontaneously in AChE immobilised layer. 10 seconds measurement was carried out every 40 s at the polarisation voltage of 300 mV and response corresponding to the enzyme reaction product amount, accumulated in the enzyme membrane, was measured. The inhibitor of the enzymatic reaction was added after response stabilisation (diffusion processes equilibrate the product consumption in the electrochemical reaction). Typical response is shown in FIG. 3. From FIG. 3, the advantages of the use of the embodiment according to the invention can be clearly seen. Very effective analysis of small sample amount can be reached by the detection of accumulated product amount in the closed vessel.

### Chemicals Used:

Biological buffer MOPSO—0.04 M MOPSO sodium salt (Sigma Aldrich), adjusted by diluted HCl to pH=7
Acetylthiocholine chloride, 25 mM (Sigma Aldrich, A-5626, cholinesterase substrate) Syntostigmin, neostigmini metilsulfas, 0.5 mg in 1 ampoule, Biotika, a.s., Slovenská Ĺup\check{c}a, S R

### Basic Measuring Solution:

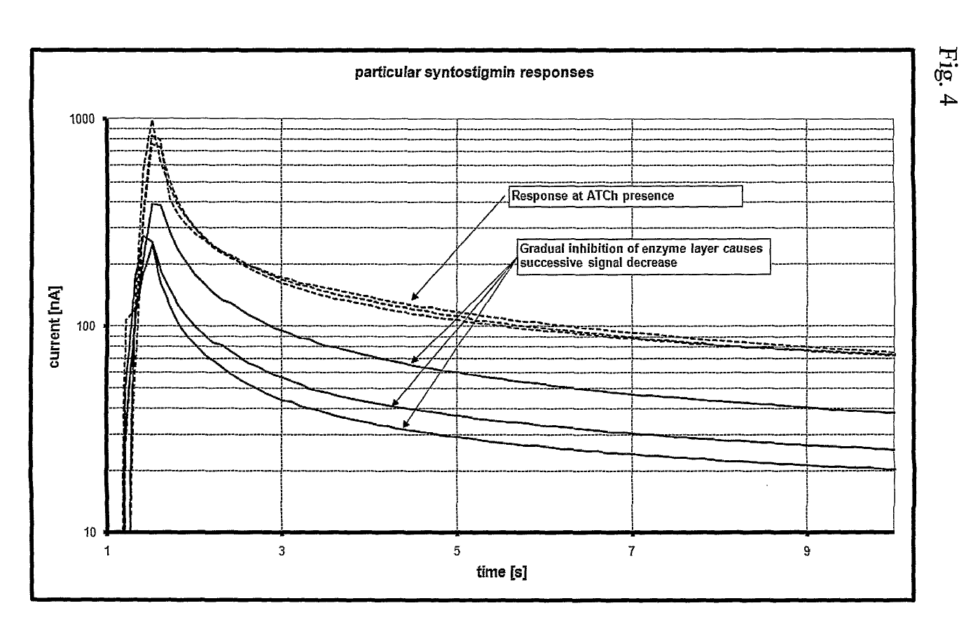

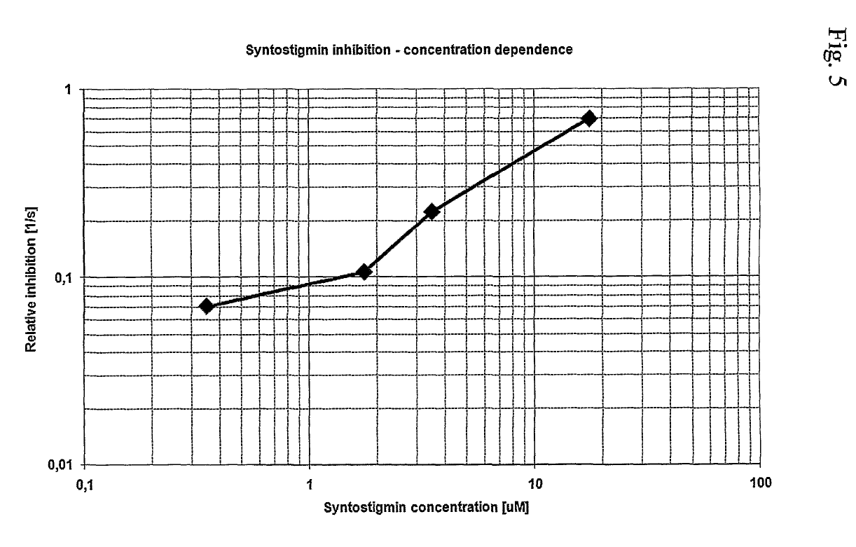

100 μl MOPSO buffer
Additions: 50 μl substrate ATCh 0.5 mM
50 μl inhibitor Syntostigmin (different concentrations tested)
   Software Beep and Synchronnous detection and Relative inhibition programs are used for measured data evaluation (BVT Technologies, a.s., www.bvt.cz).
   Response shapes and inhibitor influence on response, which causes gradual response decrease, are shown in detail in FIG. 4 (details from FIG. 3). Calibration curve for Syntostigmin concentration determination is depicted in FIG. 5.

### Example 2

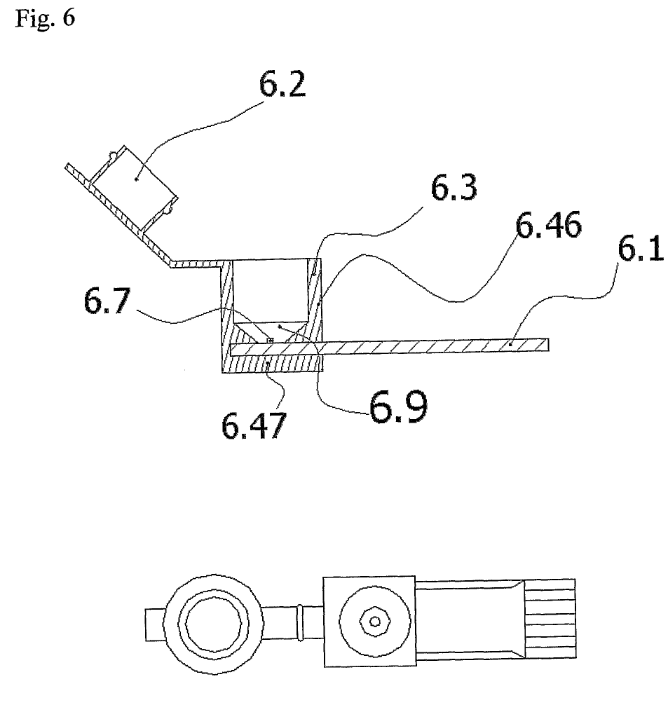

Another sensor embodiment according to the invention is shown in FIG. 6. The electrochemical sensor according to Example 2 consists of ceramic sensor substrate 6.1, onto which the electrodes are applied. These electrodes are applied e.g. by screen printing technology (the embodiment of the sensor formed on substrate 6.1 can be carried out according to patent CZ 291411 or according to other embodiments presented on www.bvt.cz). On this substrate 6.1, the reaction vessel 6.3 is formed, having base 6.47 and shell 6.46, wherein the inner side 6.9 of the shell has a conic shape tapering towards the working electrode 6.7, whereas the conic shape 6.9 is created by an appropriate adaptation of the supporting component 2.56 of the mould. The vessel 6.3 can be made of, e.g., polyethylene. The analysed solution is thus focused directly above the working electrode(s). The reaction vessel is equipped with a lid 6.2, which enables its closing.

### Example 3

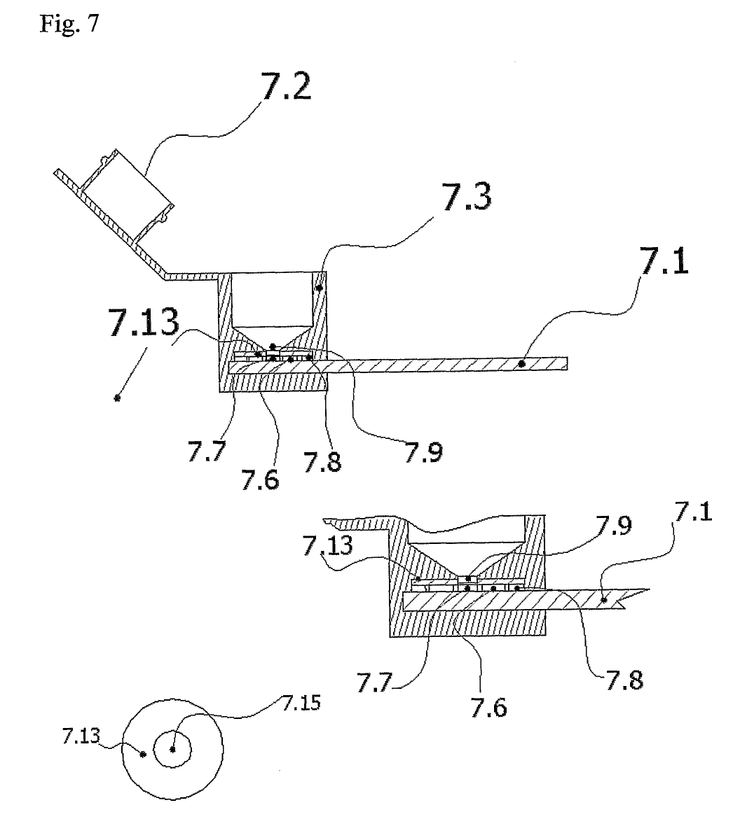

A further sensor embodiment according to the invention is shown in FIG. 7. Electrochemical sensor is created by deposition, e.g. by screen printing, of working electrode 7.7, auxiliary electrode 7.8 and reference electrode 7.6 on corundum substrate 7.1. Above the active electrodes 7.6, 7.7 and 7.8 of the electrochemical sensor is placed a membrane 7.13 with a circular opening 7.15, the diameter of which is bigger than the working electrode diameter and smaller or equal to the diameter of the conical part ending 7.9 of the vessel. The membrane 7.13 obstructs contact of the analysed liquid with reference 7.6 and auxiliary 7.8 electrodes, without blocking the conductive connection between the analysed solution and the reference electrode 7.6 and auxiliary electrode 7.8. In contrast to the heretofore known membrane uses (Jia, N. Q., Zahng, Z. R., Zhu, J. Z., Zhang, G. X., Chinese Chemical Letters 15, 3 (2004) 322), the membrane is in contact with the analysed solution solely in the proximity of the working electrode, thus eliminating the liquid ohmic resistance. This embodiments is similar to the classical use of Luggin's capillary. The membrane 7.13 is applied before mould closing by a suitable technology, e.g., by screen printing, or its shape is prepared by an independent technology, e.g., by punching or laser cutting from available membranes, and put onto the electrodes. Preferably, Nafion (www.fuelcellstore.com, type Nafion® 115CS or Nafion® 117CS) can be used as the membrane. Preferably, Nafion in solution (www.sigmaaldrich.com) or acrylamide gel saturated by KCl (www.sigmaaldrich.com) can be used for membrane application.

The membrane can be a dialysis membrane filled with solution of, e.g., KCl gel, or other porous membrane impregnated with a gel containing KCl or other salt providing conductivity such as LiCl, NaCl. The sensor is equipped with the vessel 7.3 including a conical ending, which focuses the analysed solution onto the working electrode 7.7 and with the lid 7.2 which enables closing of the reaction vessel.

Liquid interface between the analysed solution and the working solution is created by the injection of the vessel 7.3 shape including the cone ending 7.9. The vessel 7.3 can be made of, e.g., xantoprene. The membrane 7.13 also ensures that the reference electrode works at a defined concentration of, e.g., KCl in case of AgCl reference electrode, thereby a reproducible working potential setting is secured. The inserted or deposited membrane doesn't need to contain the opening 7.15. Then it overlaps also the working electrode and blocks, e.g., protein adsorption, which can influence the course of the detection electrochemical reaction.

### Example 4

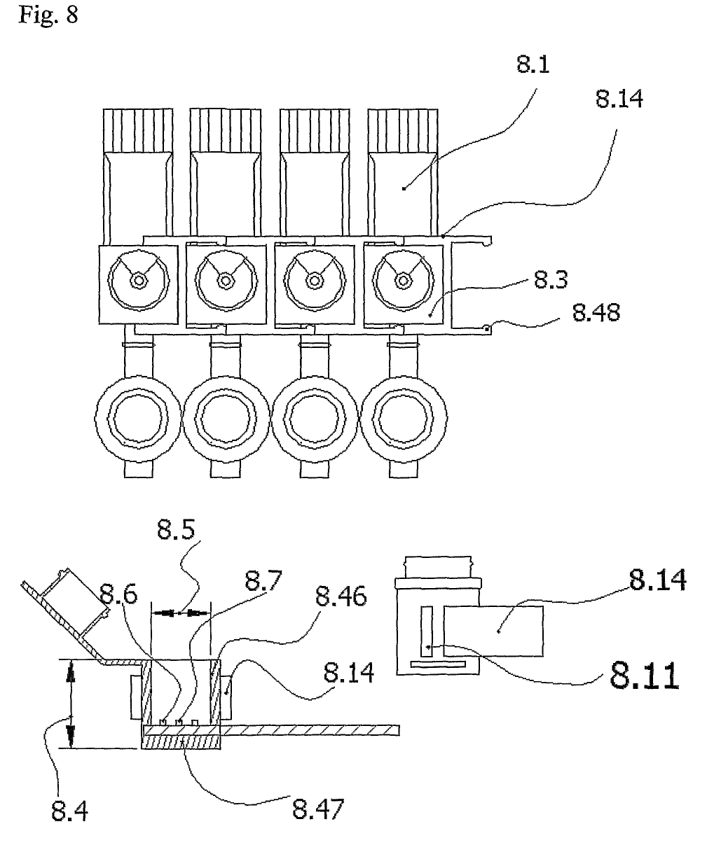

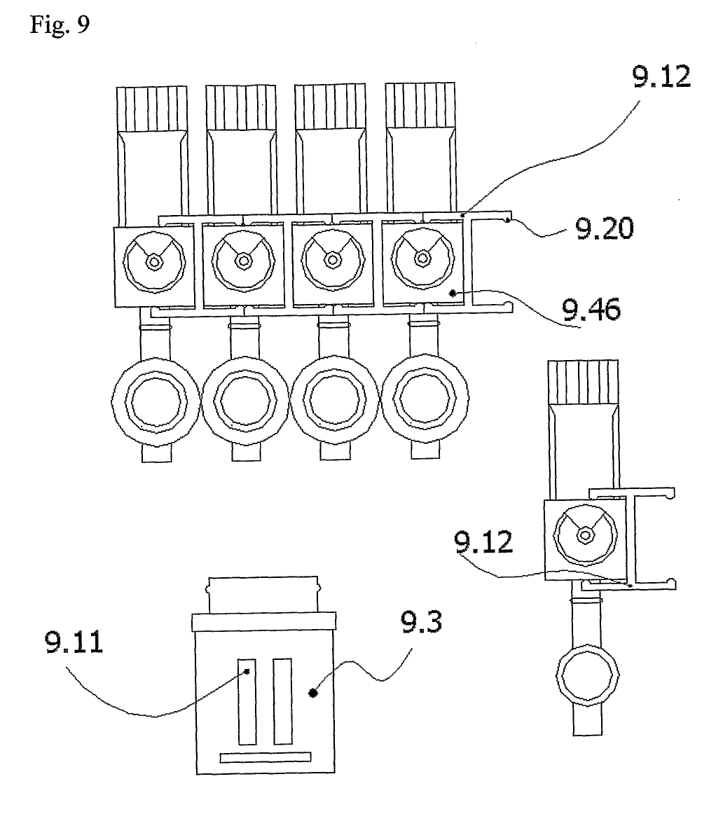

Electrochemical sensor according to Example 4 is represented in FIG. 8 and FIG. 9. The sensor contains ceramic substrate 8.1, onto which working electrode 8.7 and reference electrode 8.6 are applied. These electrodes are applied by, e.g., screen printing technology. Reaction vessel 8.3 of the height 8.4 and the reaction space diameter 8.5, with the base 8.47 is applied by injection moulding onto the sensor active surface. The vessel 8.3 can be made of, e.g., desmopane. The reaction vessel shell 8.46 is equipped with at least two notches 8.11 and at least two elastic elements 8.14 equipped with jutties 8.48, that fit into the notches 8.11. The embodiment of the reaction vessel shell 8.46 with notches 8.11 and elastic elements 8.14 with jutties 8.48 enables to assemble a linear sensor array, whereas individual sensors cannot influence each other.

Another sensor array embodiment is shown in FIG. 9. The embodiment is almost identical to the previous one with the only difference that the connecting element 9.12 is an independent component, which is not inseparably connected with the shell 9.46 of the reaction vessel 9.3 of the sensor. The shell 9.46 of the reaction vessel 9.3 of the sensor is equipped with notches 9.11 only. A linear sensor array can be assembled from the sensors, whereas no mutual influencing of detection reactions occurs.

### Example 5

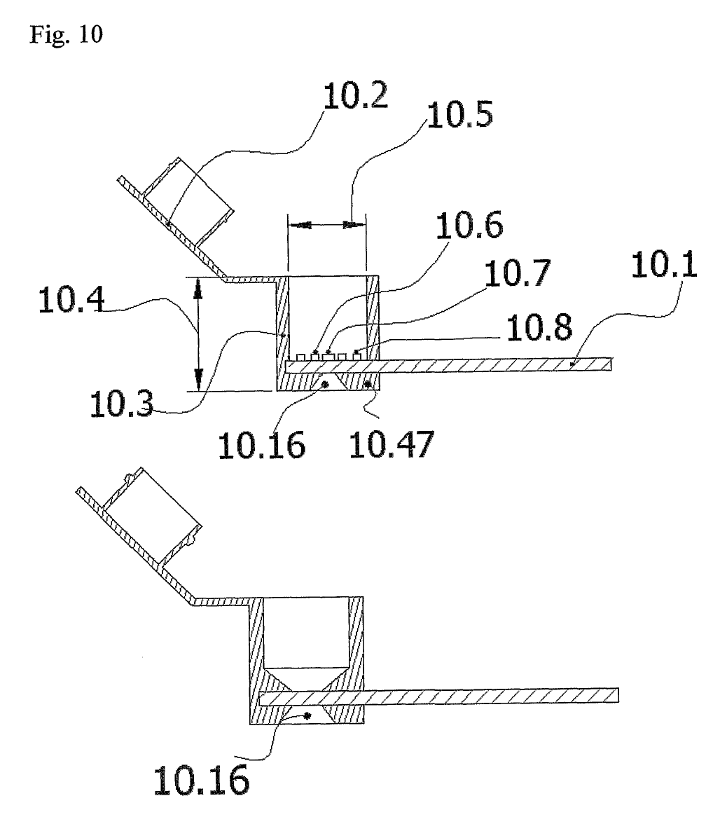

Electrochemical sensor according to Example 5 is shown in FIG. 10. The sensor contains ceramic substrate 10.1, onto which working electrode 10.7, reference electrode 10.6 and auxiliary electrode 10.8 are applied. These electrodes are applied by, e.g., screen printing technology. Onto the active area of the sensor is by injection moulding applied reaction vessel 10.3 of the height 10.4 and the diameter of reaction area 10.5, the base 10.47 of which surrounds the sensor and is provided with conical cut-out 10.16, which allows the insertion of an element, which influences processes occurring on the working electrode. The vessel 10.3 can be made of, e.g., ABS (acrylonitrile butadiene styrene). Preferably, e.g., a blunted cone of soft magnetic material and permanent magnet can be used. The blunted cone of soft magnetic material focuses magnetic field onto the working electrode. Non-homogeneous magnetic field concentrates substances tagged by magnetic nanoparticles onto the working electrode, where they are detected. The herein described arrangement can preferably be used for an embodiment, wherein the inner side of the shell is of a conical shape tapering towards the working electrode, whereas the conical shape is formed by an appropriate modification of the supporting component as indicated in Example 2 and in FIG. 6.

### Example 6

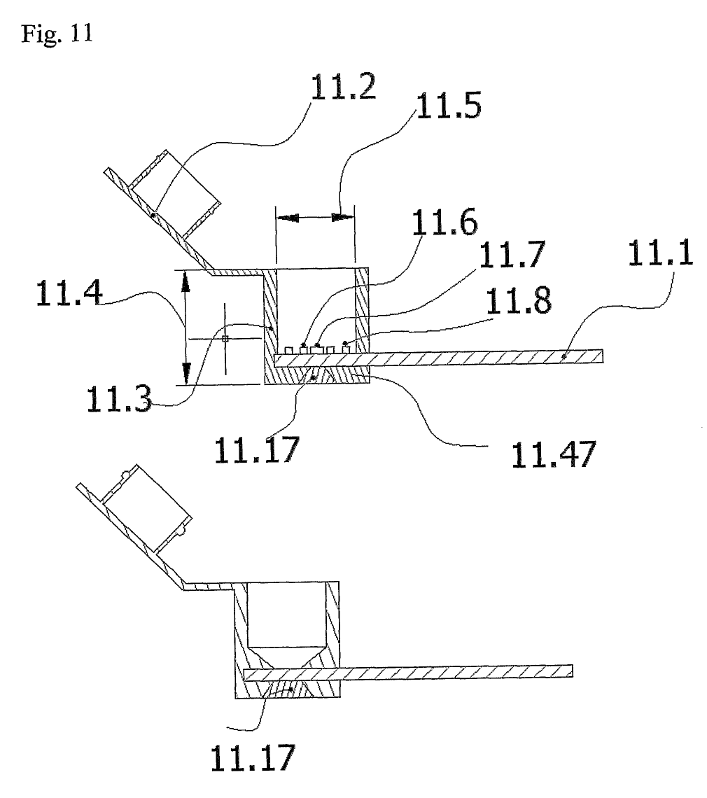

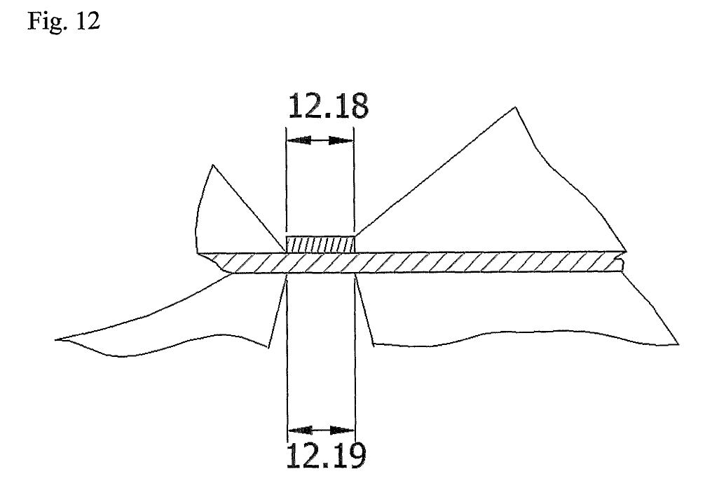

Electrochemical sensor according to Example 6 is depicted in FIG. 11 and FIG. 12. The sensor contains ceramic substrate 11.1, onto which working electrode 11.7, reference electrode 11.6 and auxiliary electrode 11.8 are applied. The electrodes are applied, e.g., by screen printing technology. Reaction vessel 11.3 of the height 11.4 and the reaction space diameter 11.5 is applied by injection moulding onto the sensor active surface. The vessel 11.3 can be made of, e.g., PBT (polybutylene terephtalate styrene). The sensor base 11.47 with conical cut-out 10.16, into which is inseparably inserted, e.g, by glueing, a conical component 11.17, which influences processes occurring on the working electrode. The conical component 11.17 is made of preferably soft magnetic material, e.g., Fe, if it is necessary to influence processes on the working electrode by magnetic field. The conical component 11.17 can be made of material with high temperature conductivity, e.g., Cu, if the processes on the working electrode have to be influenced by temperature. In order to the field influence transmitted by the cone 11.17 to be focused onto the working electrode, its diameter 12.18 (see FIG. 12) has to be bigger or equal to the diameter of the peak cone 12.19 of the inserted conical component 11.17. Described arrangement can be preferably used for the embodiment, wherein the inner side of the shell is of conical shape tapering towards the working electrode, whereas the conical shape is created by an appropriate modification of the supporting component as described in Example 2 and in FIG. 6.

### Example 7

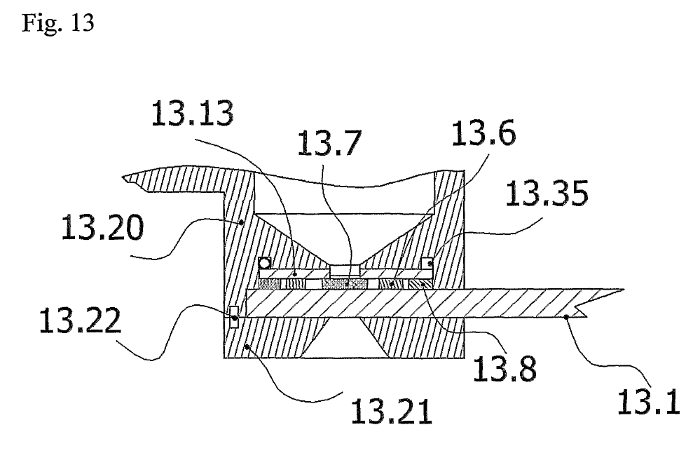

Electrochemical sensor according to Example 7 is displayed in FIG. 13. The sensor contains ceramic substrate 13.1, onto which working electrode 13.7, reference electrode 13.6 and auxiliary electrode 13.8 are applied. The electrodes are applied, e.g., by screen printing technology. Reaction vessel is produced separately from the sensor and it consists of two parts—a detached base 13.21 and a detached shell with a lid 13.20, that are equipped with a lock 13.22, which enables a subsequent inseparable assemblage of both parts. The reaction space is sealed by an “o” ring 13.35. The sensor preparation is finished by connecting the detached shell 13.20 and the detached base 13.21 by means of lock 13.22 so that the reaction space containing a membrane 13.13 sealed by “o” ring 13.35 is formed. The sensor according to this example is appropriate for the applications, in which an immobilised active layer of the sensor can be damaged during injection moulding or where nanostructures created on the surface of the working electrode can be damaged (e.g., by heat) during injection moulding.

### Example 8

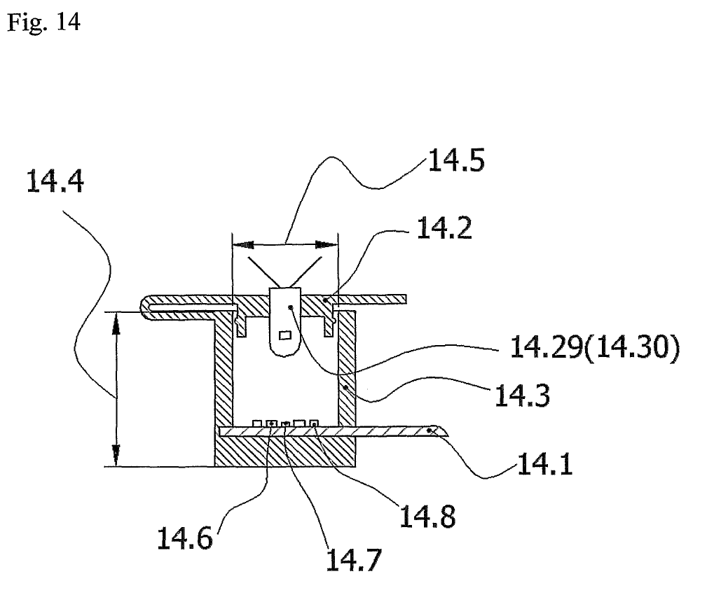

Electrochemical sensor according to Example 8 is displayed in FIG. 14. The sensor contains ceramic substrate 14.1, onto which working electrode 14.7, reference electrode 14.6 and auxiliary electrode 14.8 are applied. The electrodes are deposited, e.g., by screen printing technology. Reaction vessel 14.3 of the height 14.4 and the diameter of reaction space 14.5 is applied by injection moulding onto the sensor active surface. The vessel 14.3 can be made of, e.g., PET (polyethylene terephthalate). A light source 14.29 enabling the stimulation of processes occurring on the working electrode is inseparably inserted in the sensor lid. LED diode can preferably be used as the light source.

### Measurement Example: Exact Determination of K₃[Fe(CN)₆] Electrode Potential

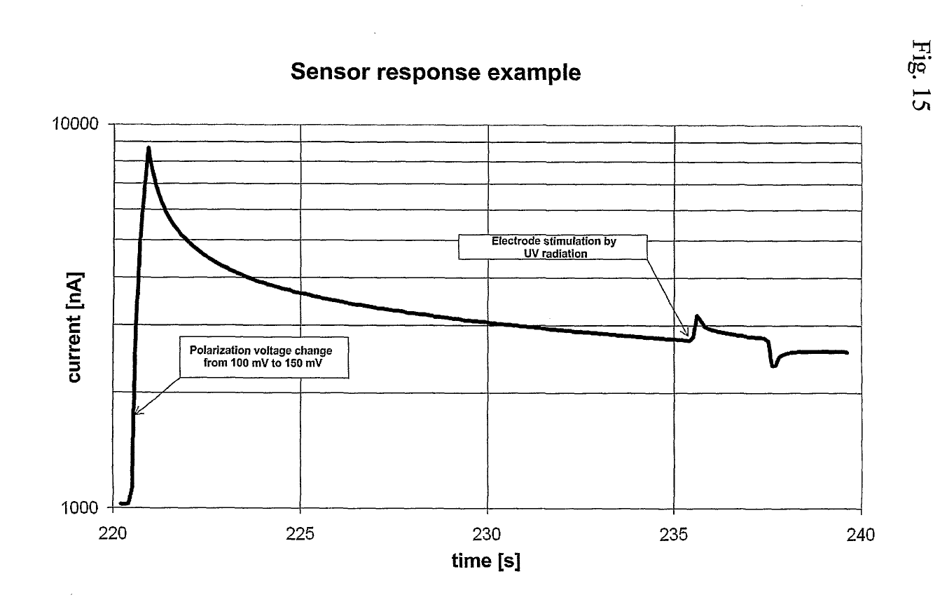

Electrochemical vessel was filled with 100 μl of 0.001 M K₃[Fe(CN)₆] solution. Working electrode was stepwise polarised from −400 mV to 600 mV, with step 50 mV. The working electrode was stimulated by LED with the maximum wavelength of 350 nm 15 s since the potential change. An example of sensor response on the polarisation voltage change from 100 mV to 150 mV and the following stimulation by UV radiation is shown in FIG. 15. The stimulation takes effect in the exponential component describing the dependence of current on polarisation voltage, i.e.,

$$I \approx \frac{1}{1 + {e}^{\frac{neα ( U - {U}_{0} ) F + hv}{RT}}}$$

If the component |neα(U−U₀)F|>>hν, then there is no effect of light. However, if neα(U−U₀)≈0, the influence of stimulating radiation will be maximum.

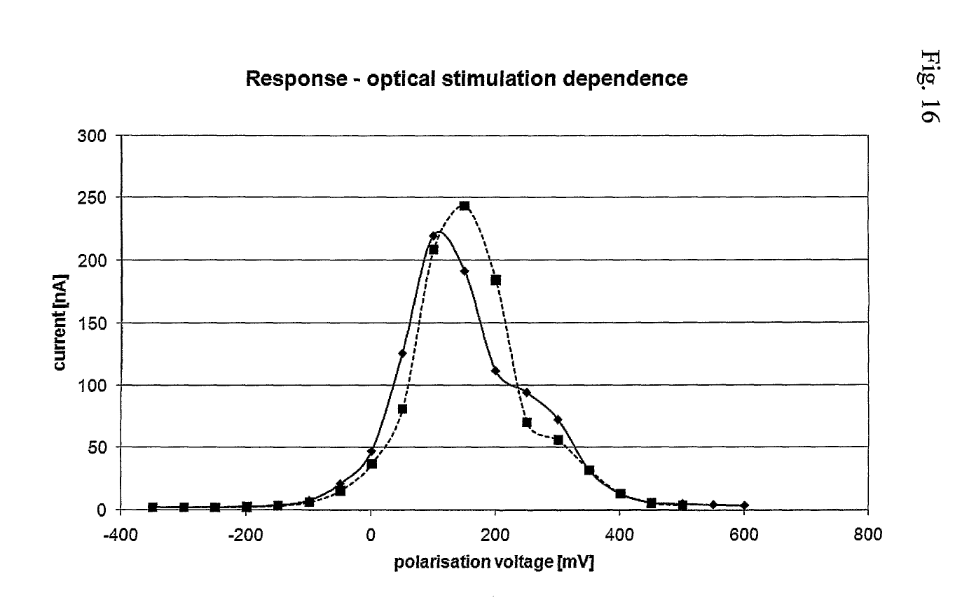

Experimental dependence of the current response on stimulation can be seen in FIG. 16. Maximum corresponds to theoretical value of U₀ at the temperature 22° C.

The embodiment described in this example is suitable for the applications, in which the electrochemical reactions can be stimulated by light.

### Example 9

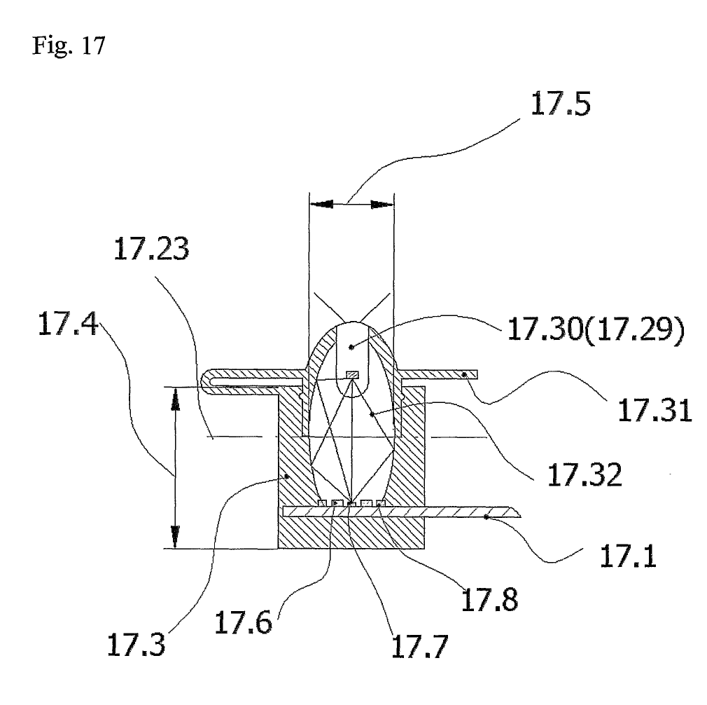

Electrochemical sensor according to Example 9 is displayed in FIG. 17. The sensor contains ceramic substrate 17.1, onto which working electrode 17.7, reference electrode 17.6 and auxiliary electrode 17.8 are applied. The electrodes are deposited, e.g., by screen printing technology. Reaction vessel 17.3 of the height 17.4 and the diameter of reaction space 17.5 is applied by injection moulding onto the sensor active surface. The vessel 17.3 can be made of, e.g., polystyrene. Light source 17.29 or light detector 17.30 is inseparately inserted in the sensor lid. Preferably, LED diode or PHOTO diode can be used. The electrochemical vessel has a shape of spheroid, whereas the plane of separation 17.23 of the lid ending part 17.31 and inner part of the reaction vessel lies in the plane determined by two half-axes of the spheroid. The light source 17.29 or light detector 17.30 are placed so that their active element lies at least in part in the focus of the spheroid and the working electrode lies in the opposite focus of the spheroid. This arrangement ensures that the light produced by the light source 17.29 is focused on working electrode, as is indicated by several rays 17.32.

The embodiment of Example 9 can work also in such a manner that the substance accumulated on the working electrode can emit light, e.g., by electroluminescence, and a photodiode 17.30, which reads the resulting light, is integrated in the lid. By focusing the light emitted by optoelectrochemical reactions on the working electrode onto the photodiode detection chip a significant sensitivity increase occurs due to electrochemical vessel shape being ellipsoid.

### Example 10

Example 10 shows a reaction vessel with two magnets, one of which is supplied with pole extension focusing magnetic field on the working electrode. The thus arising inhomogeneous magnetic field influences the reaction of paramagnetic substances on the working electrode.

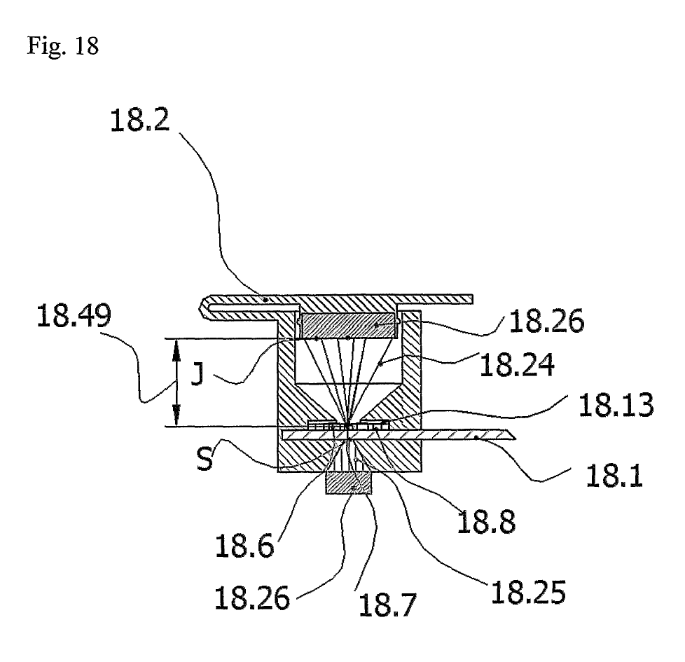

Electrochemical sensor according to Example 10 is displayed in FIG. 18. The sensor contains ceramic substrate 18.1, onto which working electrode 18.7, reference electrode 18.6 and auxiliary electrode 18.8 are applied. The electrodes are deposited, e.g., by screen printing technology. Over the active electrodes 18.6, 18.7 and 18.8 of the electrochemical sensor, a membrane 18.13 with circular opening 7.15 (see FIG. 7) is placed, the diameter of which is bigger than the diameter of the working electrode 12.18 and smaller or equal to the diameter of the conical part ending 12.19 (see FIG. 12—this part is the same as in Example 6). The lid 18.2 is equipped with a magnet 18.26, the south (north) pole of which is 2 to 20 mm far from the surface of the working electrode 18.49. The resulting inhomogeneous magnetic field changes the concentration of paramagnetic substances in the vicinity of the working electrode 18.7, thus changing its signal. This phenomenon can be used for analysis sensitivity increase of some paramagnetic substances. Main advantage of the embodiment according to Example 10 is that it is possible to create a complicated electrochemical reaction vessel with simple facilities and low costs.

### Example 11

Example 11 shows a reaction vessel equipped with two magnets for appropriate magnetic field creation. Differently from Example 10, one magnet is of a ring shape and it enables a simultaneous action of light and magnetic field on the working electrode.

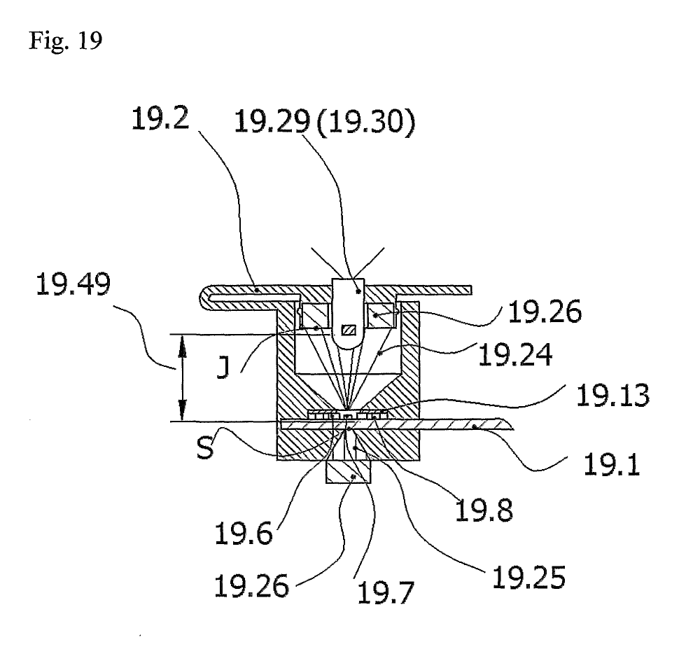

Electrochemical sensor according to Example 11 is displayed in FIG. 19 and it contains ceramic sensor substrate 19.1, onto which working electrode 19.7, reference electrode 19.6 and auxiliary electrode 19.8 are applied. These electrodes are applied, e.g., by screen printing technology (sensor arrangement created on substrate 19.1 can be carried out according to patent CZ 291411 or according to other embodiments presented at www.bvt.cz). The reaction vessel according to Example 3 and shown in FIG. 7 is applied by injection moulding on the sensor active surface. The lid 19.2 is equipped with the ring magnet 19.26. South (north) pole of the magnet 19.26 is placed in the distance 19.49 from the working electrode surface. Inside the magnet 19.26 ring there is placed a LED 19.29, which enables independent influence on phenomena on working electrode by electromagnetic radiation. The second magnet 19.26 is equipped with pole horn 19.25, which directs magnetic field onto the working electrode. In the reaction vessel there originates an inhomogeneous magnetic field, which changes the concentration namely of paramagnetic substances in the vicinity of the electrode and influences the electrode reaction. The electrode reaction can be further independently influenced by electromagnetic radiation emitted by the LED placed in the magnet. Independent influence on the signal of the working electrode by electromagnetic radiation enables a sensitivity increase with regard to Example 10 namely by using synchronous detection owing to optical stimulation by LED. The sensor with integrated reaction vessel according to the invention is connected to an evaluating unit through contacts 1.10 (see FIG. 1).

### Example 12

Example 4 shows the methods for creating one-dimensional sensor arrays. In some applications (e.g., DNA analysis) it is necessary to carry out many analyses in parallel. In such cases the one-dimensional array can be too long and difficult to manipulate with. The solution of this situation is shown in Example 12, which illustrates the arrangement of two-dimensional sensor array.

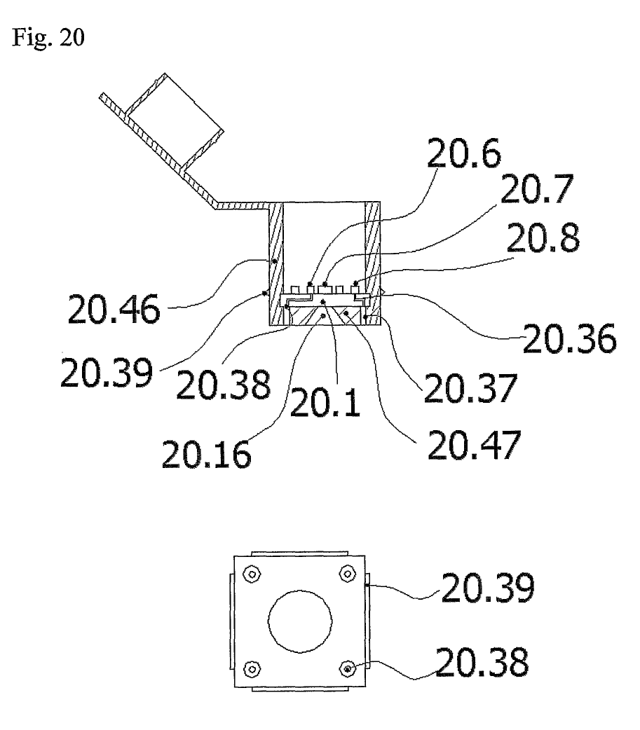

Electrochemical sensor according to Example 12 is displayed in FIG. 20 and contains ceramic sensor substrate 20.1, which is prepared for example by LTCC (Low Temperature Cofired Ceramics) technology, onto which working electrode 20.7, reference electrode 20.6 and auxiliary electrode 20.8 are applied. The electrodes are deposited, e.g., by screen printing technology. The ceramic substrate with the electrodes is equipped with contacts on the sensor bottom side 20.38 that are connected by conductive paths 20.36 with the working electrode 20.7, reference electrode 20.6 or auxiliary electrode 20.8. The conductive paths can be led inside ceramics or on its surface.

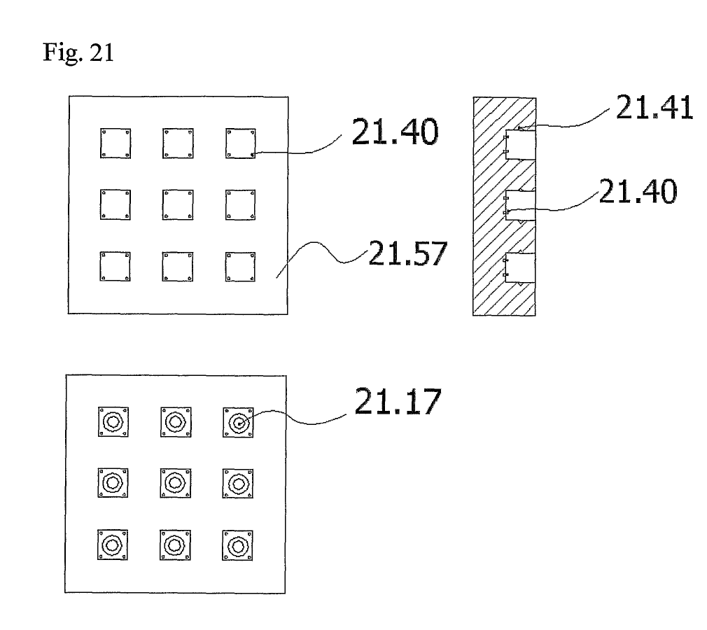

On the sensor active surface is by injection moulding applied the reaction vessel according to Example 1 with the difference that in the base 20.47 of the reaction vessel there are openings 20.37 that allow for the conductive connection of the active electrodes. The shell 20.46 of the reaction vessel is equipped with at least two juts 20.39 that allow arrestment of the reaction vessel with sensor into a contact field 21.52, which is displayed in FIG. 21. The contact field 21.52 is provided with notches 21.41, which allow click—in connection with the arrestment juts 20.39 of the reaction vessel displayed in FIG. 20. Furthermore, the contact field 21.52 contains elastic contacts 20.40, the sliding elastically mounted part of which fits into the openings 20.37 of the reaction vessel, touches the contacts on sensor bottom side 20.38 and it assures conductive connection between the sensor and the contact field 21.52. Bottoms of sensors can be equipped with conical opening 20.16 destined for a component focusing field, e.g., magnetic or thermal, onto the working electrode similarly as in Example 5. Two-dimensional field with elastic contacts can be also equipped with an array of conical components 21.17 that fit into the cut-outs. Sensors placed in this field can be equally or differently affected by conical components lock-on. The arrangement enables creating sensor array with reaction vessels allowing complicated parallel analyses like, for instance, DNA analyses.

### Example 13

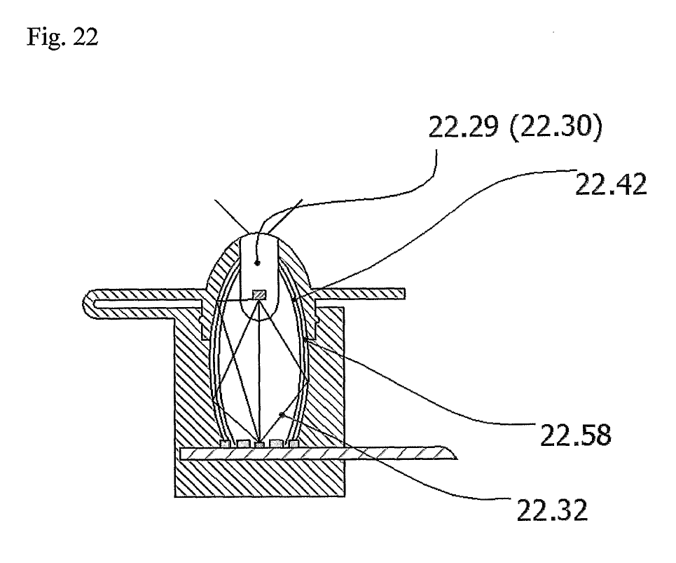

A preferred embodiment of the reaction vessel inner space in the shape of spheroid was illustrated in Example 9. This embodiment can be further improved by coating the inner surface of the reaction vessel by a material with high reflectance 22.58, e.g. Al, Au, Ag. The embodiment according to Example 13 is shown in FIG. 22.

The reaction vessel is substiantially the same as in Example 9. The reaction vessel inner walls are covered by a layer of material with high reflectance 22.58, which is applied by sputtering. This embodiment is preferred mainly in cases where the light source emits UV or IR radiation, which has poor reflectance on the plastic material surface, or in case when the photodetector 22.30 placed in the lid of the reaction vessel can be influenced by IR radiation, which passes through plastic walls of the reaction vessel. As materials with high reflectance are not chemically inert and specific and unspecific adsorption can occur with them, the material layer with high reflectance 22.58 is further covered with chemically inert material with high optical permeability 22.42. For example SiO₂ can be applied as the inert material with high optical permeability. This embodiment ensures lower losses at beam 22.32 reflection, and thus higher efficiency of the reaction vessel in optoelectrochemical measurements. The sensor with integrated reaction vessel according to the invention is connected to evaluating unit through contacts 1.10 (see FIG. 1).

### Example 14

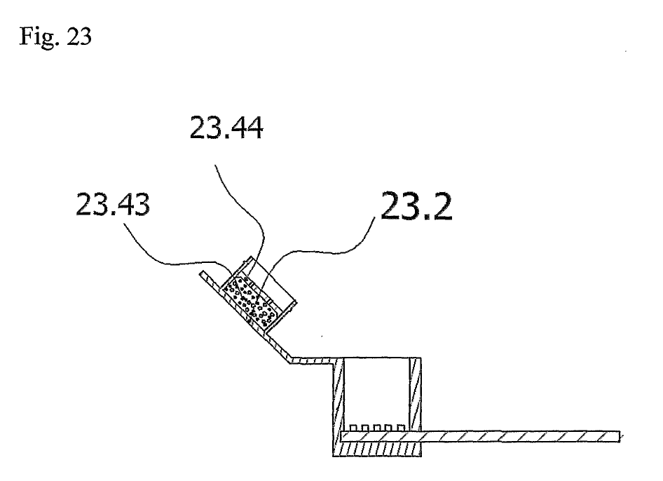

One of the main advantages of the embodiment according to the invention is the possibility to produce reaction vessels by the gross including reagents for users. It is important to ensure in this application that the chemical substances, which are lyophilised, are not degraded during storage. The embodiment is displayed in FIG. 23. Electrochemical sensor according to Example 1 is further equipped with a lid 23.2, which is equipped with an inset 23.44 made of a porous material or provided with openings that allow to accommodate in the lid particles of a siccative 23.43, e.g., silica gel, or of a material keeping a pre-defined humidity or of a material removing by absorption traces of substances that may degrade active substances in the reaction vessel with sensor. This embodiment increases the shelf life of the reaction vessels with sensors in case that they contain pre-prepared reagents.

### Example 15

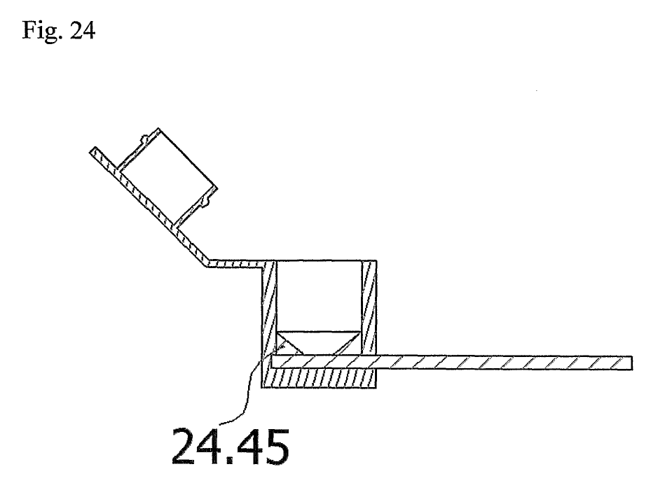

Example 15 shows another way of creating the component, which focuses substance on the working electrode and/or which allows membrane fixation according to Example 3, and another technical embodiment of which was described in Examples 3, 7 and 10 and displayed in FIG. 6, FIG. 7 and FIG. 18. The reaction vessel is substantially the same as in Example 2 with the difference that the conical embodiment 6.9, which focuses liquid onto the working electrode, is created by undetechable insertion of component 24.45, which is pressed into the inner space of the vessel. This embodiment is displayed in FIG. 24.

### Example 16

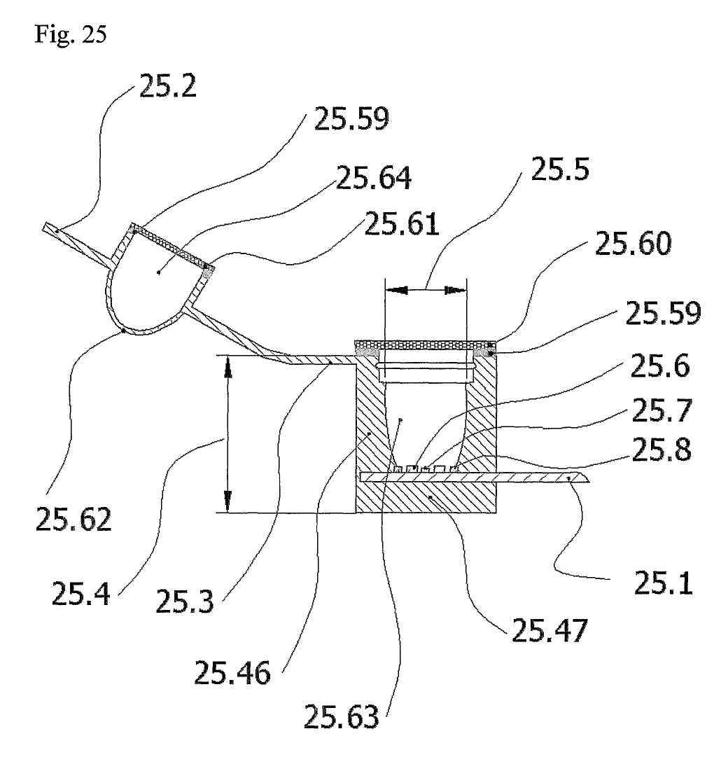

Electrochemical sensor according to Example 16 is displayed in FIG. 25 and contains ceramic sensor substrate 25.1, onto which working electrodes 25.7, reference electrode 25.6 and auxiliary electrode 25.8 are applied. These electrodes are applied for example by screen printing technology (sensor embodiment on the substrate 25.1 can be prepared according to patent CZ 291411 or according to other embodiments presented at www.bvt.cz). Reaction vessel 25.3 of the height 25.4 and the diameter of reaction space 25.5, having base 25.47 and shell 25.46 is applied by injection moulding onto the sensor active surface. The vessel 25.3 can be made of, e.g., polymethyl metacrylate. The sensor with integrated reaction vessel according to the invention is connected to the evaluating unit through contacts 1.10 (see FIG. 1). The reaction vessel 25.3 is equipped with an adhesive layer 25.59, onto which foil 25.60 is glued. Reagent A is in the inner space 25.63 of the reaction vessel, either in solution, or lyophilised. The lid of the reaction vessel is modified so that the inner space 25.64 containing reagent B is closed by a membrane 25.61, which is glued-on by the layer 25.59 or welded, e.g., by supersound. The membrane closing the space accommodating reagent B in the lid 25.2, is made of a brittle material, e.g., glass. The lid further contains an elastic part 25.62, the pressing of which cracks the membrane 25.61 and thereby the reagents A and B are mixed. The reaction vessel according to this Example enables in a very simple manner examining of the reactions that occur after mixing two reaction components A and B and that can be influenced by a tested sample. Protective foil 25.60 is removed from the reaction vessel prepared by a producer. The closing lid 25.2 is carefully put on. The membrane 25.61 tears up by its complete pressing in and reaction is thereby initiated. The whole process is carried out with the sensor connected to the measuring device and the chemical reaction of the components A and B can be followed. Due to small volumes of chemicals used and if sufficiently slow reactions are used, there is no need to mix the reaction mixture, because diffusion is sufficient for mixing.

1. An electrochemical sensor, containing a sensor substrate and at least one set of electrodes, which comprises a working electrode, a reference electrode and optionally an auxiliary electrode, characterized in that it contains at least one reaction vessel, which is tightly connected with the sensor substrate, wherein inside the reaction vessel is located at least one working electrode, whereas at least part of the sensor substrate forms the vessel bottom.

2. The electrochemical sensor according to claim 1, characterized in that the reaction vessel is made of a plastic material by injection moulding.

3. The electrochemical sensor according to claim 1, characterized in that the reaction vessel comprises a base and a shell, whereas the base is located below the sensor substrate and it is connected with the shell solely in a part of the bottom rim of the shell, wherein said part of the shell bottom rim is located in the place where a part of the reaction vessel overreaches the sensor substrate surface.

4. The electrochemical sensor according to claim 1, characterized in that the reaction vessel is equipped with a lid, preferably it is inseparably connected with the lid by means of a flexible element.

5. The electrochemical sensor according to claim 3, characterized in that the inner side of the reaction vessel shell has the shape of a blunted cone or part of the inner side of the reaction vessel shell has the shape of a blunted cone, said blunted cone tapering towards the working electrode.

6. The electrochemical sensor according to claim 5, characterized in that between the reference and auxiliary electrodes on one side and the reaction vessel inner space on the other side is placed a conductive membrane with a circular opening, the diameter of which is bigger than the diameter of the working electrode and smaller or equal to the diameter of the conical inner side ending of the reaction vessel shell or its part.

7. The electrochemical sensor according to claim 4, characterized in that the inner side of the reaction vessel shell and the inner side of the lid have the shape of an ellipsoid surface or an ellipsoid surface part, preferably wherein said ellipsoid has a focus identical with the working electrode location.

8. The electrochemical sensor according to claim 7, characterized in that a light source, preferably a LED diode, or a photodetector is placed in the second focus of the ellipsoid.

9. The electrochemical sensor according to claim 7, characterized in that the inner side of the reaction vessel shell and the inner side of the lid are coated by a light reflecting material, and preferably the layer of the light reflecting material is further coated by a layer of chemically inert material with high optical transmission.

10. The electrochemical sensor according to claim 1, characterized in that it is equipped with connecting elements for sensor arrays formation, preferably said connecting elements are locks and cut-outs or notches for inserting the corresponding connecting elements.

11. The electrochemical sensor according to claim 1, characterized in that the sensor substrate is equipped with a heating element and preferably it is further equipped with an element for sensor temperature measurement.

12. The electrochemical sensor according to claim 1, characterized in that a cut-out is formed in the reaction vessel base, said cut-out enabling the insertion of an element influencing the processes on the working electrode.

13. The electrochemical sensor according to claim 4, characterized in that the reaction vessel lid contains a substance influencing characteristics of electrode materials and/or of substances placed in the reaction vessel or it contains reagents.

14. The electrochemical sensor according to claim 13, characterized in that at least part of the reaction vessel lid is made of an elastic material and that said lid, optionally also the vessel are closed by a membrane made of brittle material.

15. A method of manufacturing the electrochemical sensor according to claim 1, characterized in that it comprises an injection moulding step, in which a sensor or its part is inserted into a mould, which is shaped so that it is possible to achieve the desired reaction vessel shape containing the base and the shell, a plastic material is subsequently injected into the mould under the pressure in the range of 1 to 1000 MPa, preferably in the range of 1 to 100 MPa, and the temperature in the range of 100 to 300° C. and the resulting product is then cooled.

16. The method of manufacturing the electrochemical sensor according to claim 1, characterized in that the base and the shell are produced independently and separately from the sensor substrate, subsequently the base is placed below the substrate onto the opposite side than that on which the electrodes are located and the shell is placed onto the substrate so that inside it is located the working electrode, and a sealing element, is inserted between the shell and the substrate, and the base and the shell are then connected by a mechanical connecting element.
